(19) United States
(12) Patent Application Publication
(10) Pub. No.: US 2007/0296521 A1
(43) Pub. Date: Dec. 27, 2007

(54) Duplexer

(75) Inventor: Edgar Schmidhammer, Stein (DE)

Correspondence Address: FISH & RICHARDSON PC, P.O. BOX 1022, MINNEAPOLIS, MN, 55440-1022, US

(73) Assignee: EPCOS AG, Munchen (DE)

(21) Appl. No.: 11/630,406

(22) PCT Filed: May 24, 2005
(86) PCT No.: PCT/EP05/05615

§ 371 Date: May 1, 2007

(30) Foreign Application Priority Data
Jun. 29, 2004 (DE) 10 2004 031 397.0

(51) Int. Cl. H03H 9/70

(52) U.S. Cl. 333/133

(57) ABSTRACT

The invention relates to a duplexer with a transmit-receive path, which branches on the output side into a receive path and a transmit path. The receive path is preferably designed on the input side for transmitting an asymmetric signal and on the output side for transmitting a symmetric signal. A receive filter, which operates with surface acoustic waves, is arranged in the receive path. A transmit filter, which operates with bulk acoustic waves, is arranged in the transmit path. The filters are preferably constructed as separate chips, which are mounted on a common carrier substrate.

The invention relates to a duplexer which is provided, in particular, for separating transmit and receive signals of a mobile telecommunications band.

A duplexer which operates with surface acoustic waves (SAW) is known from publication US 2001/0013815 A1. A balanced-to-unbalanced transformer is realized in the receive and transmit filters by a DMS track connected to series resonators.

Another duplexer, in which the receive filter is a reactance filter in a ladder-type construction is known from publication US 2002/0140520 A1. The receive filter is connected on the output side to a balanced-to-unbalanced transformer or to another element for circuit balancing of the ladder-type arrangement. The balanced-to-unbalanced transformer can also be realized by LC components or by an arrangement of SAW or BAW resonators (BAW=Bulk Acoustic Wave). The use of elements constructed using different technologies (SAW, BAW) in one filter circuit, e.g., on one and the same base substrate, is associated with high expense.

The problem of the present invention is to specify a duplexer, which is distinguished by high power compatibility.

This problem is solved according to the invention by a duplexer with the features of claim 1. Advantageous configurations of the invention follow from the other claims.

The invention specifies a duplexer which has a receive path and a transmit path. These paths can be connected to a common transmit/receive antenna. A receive filter operating with surface acoustic waves is arranged in the receive path. A transmit filter operating with bulk acoustic waves is arranged in the transmit path.

In comparison to thin-film technology—FBAR technology—SAW technology has the advantage that it is simpler to produce. For filter structures that are suitable for transmitting HF signals above 1 GHz, especially above 2 GHz, however, SAW technology has the disadvantage of low power compatibility due to low finger width. Therefore, the construction of the transmit filter in thin-film technology is especially advantageous for applications at ca. 2 GHz and above.

The transmit filter, which operates with bulk acoustic waves, has the advantage of low insertion loss in the pass band.

The receive filter is advantageously a bandpass filter. The transmit filter is preferably also a bandpass filter. The transmit filter can also be a low-pass filter, however.

The filters are preferably constructed as two separate chips. The chip in which the receive filter operating with surface acoustic waves is realized is designated as the SAW chip. The chip, in which the transmit filter operating with bulk acoustic waves is realized, is designated as the BAW chip. The chips can be unhoused in one variant. In another variant, the chips can each have a housing. The transmit-receive path is preferably arranged in a carrier substrate on which the chips are mounted and connected electrically.

The distance between the SAW chip and the BAW chip preferably equals at least λ/1000, where λ is the free-space wavelength for a center frequency of the component. The center frequency is typically a frequency arranged between the transmit band and the receive band of the duplexer.

The spatial and structural separation of the transmit path and the receive path from each other provides improved isolation between the transmit signal and the receive signal. In addition, metal shielding, which preferably lies at ground potential, can be provided between the SAW chip and the BAW chip.

The component structures constructed using thin-film technology are distinguished by high quality and high power compatibility.

The carrier substrate can be a ceramic substrate with hidden, structured metal layers, in which the structures of the transmit-receive path—e.g., capacitors, inductors, and/or resistors—are realized. Non-linear or active components can be arranged on or in the carrier substrate: diodes, switches, various micromechanical switches, power amplifiers, and low-noise amplifiers. The carrier substrate is also used for dissipating the heat generated, in particular, in the transmit filter.

The carrier substrate can also be produced from a different material, e.g., FR4, LCP (liquid-crystalline polymers), or Si.

FBAR resonators can be membrane-like thin-film resonators. Alternatively, FBAR resonators can also have an acoustic reflector.

In one variant of the invention, the transmit filter can have several BAW resonators, which are connected to each other in a ladder-type construction.

In another embodiment, the transmit filter has a resonator stack arranged in the transmit path with two resonators stacked one on top of the other. The resonators can have a common electrode. In a preferred variant, an acoustic, partially transparent coupling layer, which separates the resonators galvanically from each other, is arranged between the resonators.

In the receive path, in addition to the receive filter, other circuits can be provided, which are preferably connected to the receive filter in series. These circuits can have SAW component structures or other elements, among other things, BAW component structures. These circuits can realize, e.g., a balanced-to-unbalanced transformer or an impedance converter converter. The other circuits arranged in the receive path can be formed, e.g., from conductive tracks, which are arranged in the metal layers of the carrier substrate. The BAW component structures, which are arranged in the receive path, can be arranged, e.g., on the BAW chip with the transmit filter.

The receive path is preferably divided symmetrically on the output side or divided into two sub-paths. The receive path can also be asymmetric on the output side.

The receive filter is preferably connected in an asymmetric/symmetric arrangement. The transmit filter is preferably constructed with two asymmetric electric ports and connected into an asymmetric transmit path. The transmit path can also be constructed asymmetrically on the output side (antenna side) and symmetrically on the input side.

In one variant of the invention, the receive filter can have an asymmetric electric port on both the input side and the output side, wherein preferably a balanced-to-unbalanced transformer is preferably connected after the port. In another variant of the invention, the receive filter can also have two symmetric electric ports, wherein a balanced-to-unbalanced transformer is connected before the port.

A balanced-to-unbalanced transformer can be constructed as a DMS track or a resonator stack connected accordingly (see FIG. 16).

In the following, the invention is explained in more detail with reference to embodiments and the associated figures. The figures show various embodiments of the invention with reference to schematic representations that are not true to scale. Identical or identically acting parts are designated with the same reference symbols. Shown schematically are

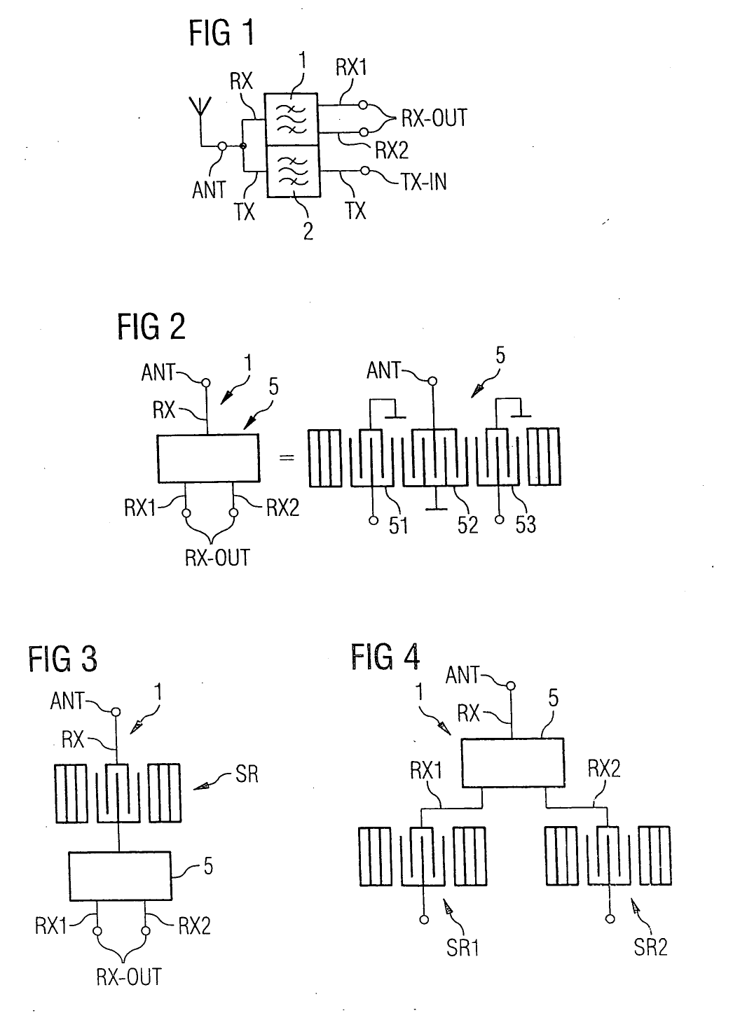

FIG. 1, a duplexer according to the invention,

FIG. 2, the receive filter with a DMS track,

FIG. 3, the receive filter with a DMS track which is connected on the input side with a series resonator,

FIG. 4, the receive filter with a DMS track which is connected on the output side with two series resonators,

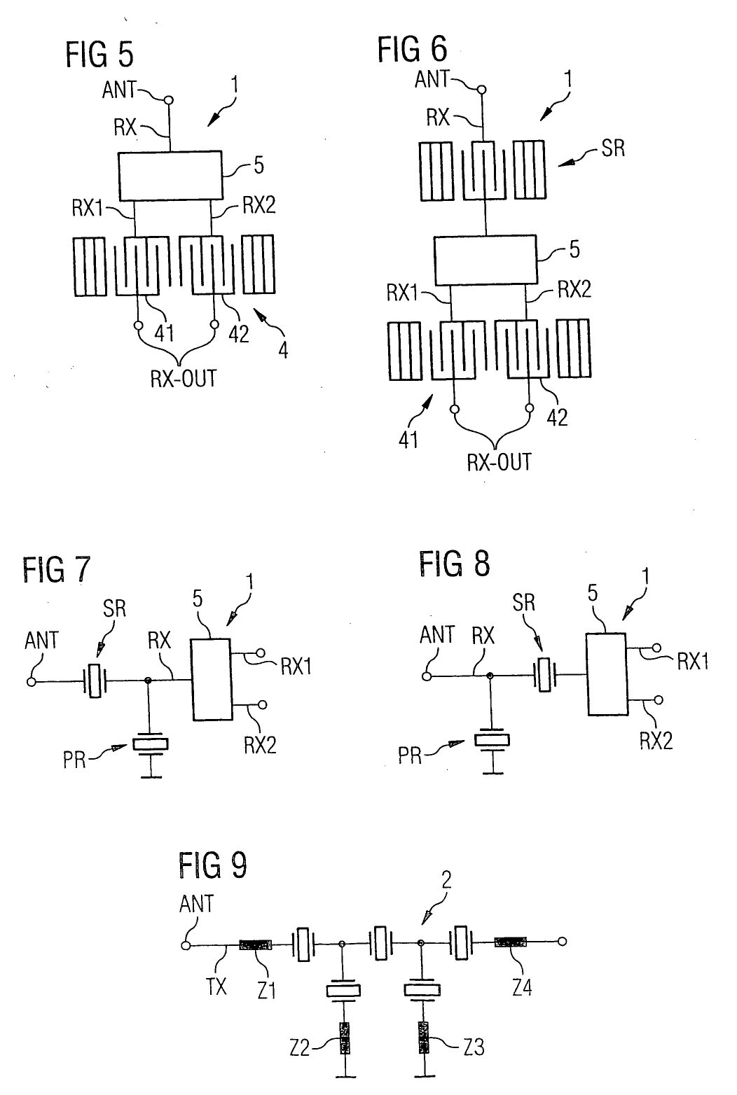

FIG. 5, the receive filter with a DMS track which is connected on the output side with a two-port resonator,

FIG. 6, the receive filter with a DMS track which is connected on the input side with a series resonator and on the output side with a two-port resonator,

FIG. 7, the receive filter with a DMS track which is connected with a ladder-type element,

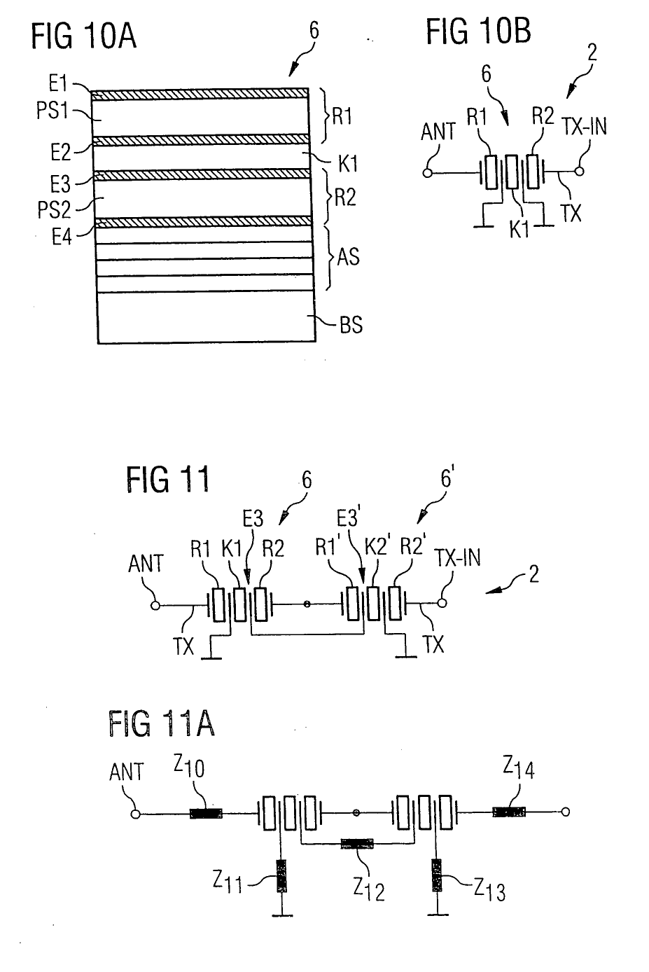

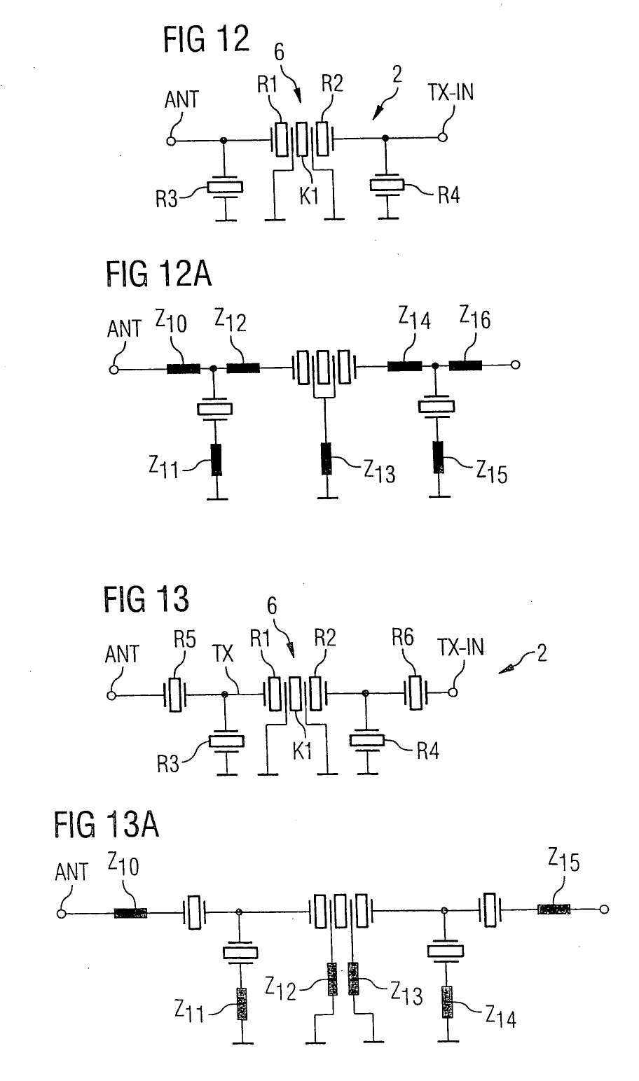

FIG. 8, the receive filter with a DMS track which is connected with a ladder-type element,

FIG. 9, a transmit filter with BAW resonators in a ladder-type construction,

FIG. 10A, a transmit filter with a resonator stack which comprises BAW resonators,

FIG. 10B, an equivalent circuit diagram of the transmit filter with the resonator stack according to FIG. 10A,

FIGS. 11, 11A, each a transmit filter with two resonator stacks connected one behind the other,

FIGS. 12, 12A, each a transmit filter with a resonator stack and two parallel resonators,

FIGS. 13, 13A, each a transmit filter with a resonator stack which is connected with series resonators and also parallel resonators,

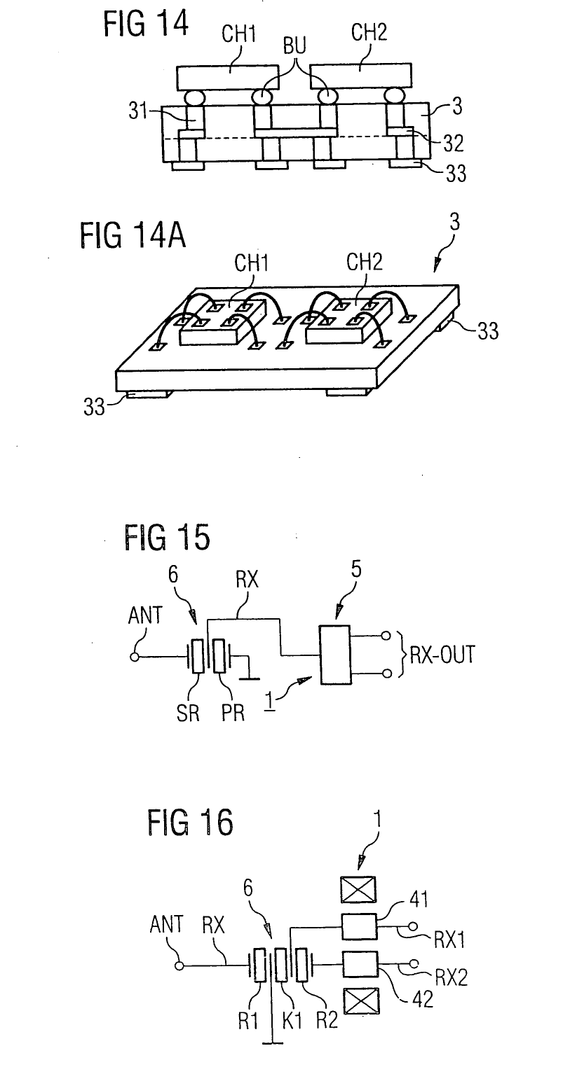

FIGS. 14, 14A, each a component with a duplexer according to the invention in a schematic cross section,

FIG. 15, a receive filter with a DMS track which is connected with a ladder-type element realized as a BAW resonator stack,

FIG. 16, a receive filter with a two-port resonator and a balanced-to-unbalanced transformer connected before the resonator.

In FIG. 1, a duplexer according to the invention is shown with a transmit path TX and a receive path RX. The receive path RX is divided on the output side into two sub-paths RX1 and RX2 and is suitable for transmitting a symmetric signal. The duplexer has a receive filter 1 arranged in the receive path and a transmit filter 2 arranged in the transmit path. The receive filter 1 operates with surface acoustic waves. The transmit filter 2 operates with bulk acoustic waves.

The receive filter 1 is arranged between an antenna port ANT and a receive output RX-OUT. The receive filter is constructed asymmetrically on the input side (i.e., antenna side). On the output side, this filter is constructed symmetrically. Thus, the receive filter is simultaneously a balanced-to-unbalanced transformer.

The transmit filter 2 is arranged between the antenna port ANT and the transmit input TX-IN. In this example, the transmit filter is constructed asymmetrically on the input side and also on the output side.

In FIG. 2, a receive filter 1 is shown, which has a DMS track 5 connected asymmetrically on the input side and symmetrically on the output side with three transducer converters 51, 52, 53. The acoustic track is limited by two acoustic reflectors. The transducer converters are arranged one next to the other in the acoustic track and coupled acoustically to each other. The input transducer converter 52 is arranged between two output transducer converters 51 and 53 and not connected electrically to these transducer converters.

The input transducer converter 52 is arranged in the receive path RX on the input side. The output transducer converter 51 is arranged in a sub-path RX1 of the symmetric receive path RX. The output transducer converter 53 is arranged in the sub-path RX2 of the receive path RX.

The DMS track can also have more than only three transducer converters, wherein the input and output transducer converters are arranged preferably alternately in the acoustic track.

The receive filter 1 can be composed of the DMS track, as shown in FIG. 2. It is also possible, however, for the DMS track to form only a portion of the receive filter 1. Other variants of the receive filter with a DMS track are presented in FIGS. 3 to 8.

FIG. 3 shows the DMS track 5, which is connected on the input side to a series resonator SR. The series resonator is a resonator operating with surface acoustic waves. The series resonator SR is connected to the input transducer 52 of the DMS track (cf. FIG. 2) in series and arranged in the receive path RX.

In FIG. 4, another receive filter 1 is presented, in which the DMS track 5 is connected on the output side with two series resonators SR1 and SR2 operating with surface acoustic waves. The series resonator SR1 is connected in series to the output transducer converter 51 (cf. FIG. 2) and arranged in the sub-path RX1 of the receive path. The series resonator SR2 is connected in series to the output transducer 52 and arranged in the sub-path RX2 of the receive path.

It is possible to arrange a series resonator like in FIG. 3 in the asymmetric part of the receive path RX in the variant presented in FIG. 4.

In FIG. 5, a receive filter 1 with the DMS track 5 is shown, which is connected in series on the output side to a two-port resonator. The two-port resonator represents an acoustic track 4 limited by acoustic reflectors with two transducer converters 41 and 42 arranged one next to the other.

The first output transducer converter 51 of the DMS track is connected in series to the transducer converter 41 arranged in the acoustic track 4. This series circuit is arranged in the sub-path RX1. The second output transducer 52 of the DMS track is connected in series to the transducer converter 42 arranged in the acoustic track. This series circuit is arranged in the sub-path RX2.

In FIG. 6, a receive filter 1 is shown, in which the DMS track 5 is connected on the input side as in FIG. 3 to a series resonator SR and on the output side as in FIG. 5 with a two-port resonator 41, 42.

In FIGS. 7, 8, a receive filter is shown with the DMS track 5 according to FIG. 2, which is connected in series to a ladder-type element in the receive path RX on the input side. The ladder-type element is composed of a series resonator SR and a parallel resonator PR. The resonators SR and PR preferably work with surface acoustic waves. It is also possible, however, for the ladder-type element to be composed of BAW resonators.

In FIG. 7, the parallel resonator PR is connected downstream of the series resonator SR. In FIG. 8, the parallel resonator PR is connected upstream of the series resonator SR. In principle, arbitrarily many series resonators or parallel resonators can be arranged in the receive path or connected upstream of the DMS track 5.

FIG. 9 shows a transmit filter 2, which is realized in a ladder-type construction and has several resonators. All of the resonators in the arrangement described here work with bulk acoustic waves (BAW).

Several series resonators are arranged in the transmit path TX. Two transverse branches, which lead to ground and which each include a parallel resonator, are connected to the transmit path TX. In addition, impedances Z1 to Z4, which can be formed, for example, by the inductors of the electric ports of a housing, are provided in the TX signal path and also in the transverse branches.

FIG. 10A shows a resonator stack 6, which, according to another variant, is part of the transmit filter 2, operating with bulk acoustic waves. The resonator stack 6 is composed of a first resonator R1, a second resonator R2 arranged underneath, and a coupling layer K1, through which the two resonators R1, R2 are coupled acoustically to each other. The first resonator has a piezoelectric layer PS1, which is arranged between electrodes E1 and E2. The resonator R2 has a piezoelectric layer PS2, which is arranged between the electrodes E3 and E4. An acoustic reflector AS is arranged between the resonator stack 6 and a base substrate BS.

FIG. 10B shows an electrical equivalent circuit diagram of a transmit filter with the resonator stack 6 according to FIG. 10A.

The resonator stack 6 can form the complete transmit filter 2. In addition to the resonator stack 6, the transmit filter can have other elements; see FIGS. 11 to 13.

In FIG. 11, a transmit filter is shown with two resonator stacks connected to each other in series electrically.

In addition to the first resonator stack 6, in the transmit path TX another resonator stack 6′ is arranged, in which another coupling layer K2, which is acoustically semi-transparent, is arranged between the resonators R1′ and R2′.

The resonators R1′ and R2′ are coupled to each other acoustically by the coupling layer K2. An electrode E3 of the first resonator stack 6 facing the coupling layer K1 is connected electrically to an electrode E3′ of the second resonator stack 6′ facing the coupling layer K2.

In FIGS. 11A, 12A, and 13A, impedances Z10 to Z16, which can be formed, e.g., by the inductors of the electrical ports of a housing, are provided in the TX signal path and also in the transverse branches. The impedances Z10 to Z16 can also be capacitors.

In FIG. 12, another transmit filter is shown with a resonator stack, which is connected to other BAW resonators. A transverse branch with a parallel resonator R3, R4 arranged in this branch and operating with bulk acoustic waves is provided on the input and output sides between the transmit path TX and ground.

FIG. 13 shows another transmit filter with a resonator stack, which is connected in series with a ladder-type element on the input and output sides.

The series resonators R5, R6 are BAW resonators, which are arranged in the transmit path TX. The series resonator R5 and the parallel resonator R3 together form a ladder-type element on the input side. The series resonator R6 and the parallel resonator R4 together form a ladder-type element on the output side. The resonator stack 6 can be connected, in principle, with an arbitrary number of ladder-type elements.

In FIG. 14, a component with a duplexer according to the invention is shown in schematic cross section. A SAW chip CH1 and also a BAW chip CH2 are mounted in a flip-chip construction on a carrier substrate 3. The chips CH1, CH2 are fixed to the carrier substrate 3 by means of bumps BU and connected to each other electrically. The carrier substrate 3 has several dielectric layers, between which metal layers 32 are constructed with structured conductor tracks. The conductor tracks realize hidden electrical structures, which can realize, in particular, a part of the duplexer circuit. The metal layers are connected electrically to each other and also to the chips CH1, CH2 and external ports 33 by means of through-hole contacts 31.

The chips CH1, CH2 are preferably so-called naked chips. It is possible, however, for these chips to be provided as housed components and connected to the carrier substrate electrically and mechanically by means of SMD technology (Surface Mounted Design). The carrier substrate 3 preferably forms a part of a housing, which, in one variant, encloses both chips CH1 and CH2 in a common hollow space or in separate hollow spaces.

A component or module formed in this way (modular with two chips-independent of each other) has the advantage that the crosstalk between the receive path and the transmit path is low due to the spatial separation between the chips CH1, CH2. The use of a common carrier substrate 3 has the advantage that the interfaces between the antenna, the receive filter, and the transmit filter are hidden in the module and therefore are “well defined” in terms of electrical adaptation for later applications. Good impedance matching reduces the signal losses.

In FIG. 14A, another component is shown with a duplexer according to the invention. The SAW chip CH1 and also the BAW chip CH2 are mounted on the surface of the carrier substrate 3 and connected electrically to these chips by means of bond wires.

In FIG. 15, a receive filter 1 is shown, which is constructed as a DMS track 5 and is connected to a resonator stack 6 operating with bulk acoustic waves. The resonators SR and PR are arranged one above the other in the resonator stack 6. The series resonator SR is arranged in the receive path RX on the input side. The parallel resonator PR is arranged in a transverse branch which runs between the receive path RX and ground. The resonators SR, PR are coupled to each other acoustically and also electrically.

In FIG. 16, a receive filter 1 constructed as a resonator filter or a two-port resonator is shown, in which the transducer converters 41, 42 arranged in different sub-paths RX1, RX2 of the receive path are arranged in an acoustic track and coupled acoustically to each other. The receive filter here is connected symmetrically/asymmetrically and connected on the input side electrically with the symmetric port of a balanced-to-unbalanced transformer. The balanced-to-unbalanced transformer represents a resonator stack 6 according to FIG. 10A. The resonators R1 and R2 are electrically isolated from each other by the coupling layer K1. The resonator R2 forms the symmetric port. The resonator R1 is arranged in a transverse branch connected to the receive path RX.

The invention is not limited to the embodiments shown here. The presented elements can be combined with each other in arbitrary numbers and arrangements.

In addition to the SAW chip and BAW chip, other components (e.g., switches, diodes, coils, capacitors, resistors, other chips) can be arranged on the carrier substrate. The receive filter can be asymmetric on the input side and output side. The receive filter can simultaneously realize an impedance converter, wherein its output impedance (e.g., 50 to 200 Ohm) is preferably selected higher than its input impedance (e.g., 50 Ohm). The transmit filter can simultaneously realize an impedance converter, wherein its output impedance (e.g., 50 Ohm) is preferably selected higher than its input impedance (e.g., 10 to 50 Ohm).

### LIST OF THE REFERENCE SYMBOLS

ANT Antenna port
TX-IN Transmit input
RX-OUT Receive output
RX Receive path
RX1, RX2 Sub-paths of receive path RX
TX Transmit path
TR Transmit-receive path
1 Receive filter
2 Transmit filter
3 Carrier substrate
31 Through-hole contact
32 Metal layer
33 Port
4 Acoustic track of a two-port resonator
41, 42 Transducer converters arranged in the acoustic track 4
CH1 Chip with the receive filter 1
CH2 Chip with the transmit filter 2
BU Bumps
5 DMS track
51, 53 Output transducer converters of DMS track
52 Input transducer converters of DMS track
6 Resonator stack
BS Base substrate
AS Acoustic reflector
E1 to E4 Electrodes
PS1, PS2 Piezoelectric layer
K1, K2 Coupling layer
R1, R2 BAW resonators arranged one above the other
R1′, R2′ BAW resonators arranged one above the other
R3, R4 Parallel resonators (BAW)
SR, SR1, SR2 Series resonators (SAW)
PR Parallel resonators (SAW)
Z1 to Z4 Impedance

1. Duplexer with a receive path (RX) and a transmit path (TX), with a receive filter (1), which is arranged in the receive path (RX) and operates with surface acoustic waves, and with a transmit filter (2), which is arranged in the transmit path (TX) and operates with bulk acoustic waves.

2. Duplexer according to claim 1, with a receive path (RX), which is constructed asymmetrically on the input side and which is constructed symmetrically on the output side and has two sub-paths (RX1, RX2).

3. Duplexer according to claim 2, in which the receive filter has a DMS track, which is connected asymmetrically on the input side and symmetrically on the output side and has two output transducers (51, 53) and an input transducer (52) arranged in-between.

4. Duplexer according to claim 2, with a resonator stack (6), which has resonators operating with BAW, of which at least one is arranged in the receive path (RX) and is connected in series with the receive filter (1).

5. Duplexer according to claim 1, in which an acoustic track (4) is provided with two transducers (41, 42), which are arranged one next to the other and which are each arranged in different sub-paths (RX1, RX2) of the receive path (RX).

6. Duplexer according to claim 5, in which the receive filter has a DMS track, which is connected asymmetrically/symmetrically and whose symmetrically connected side is connected in series to the transducers arranged in the acoustic track.

7. Duplexer according to claim 4, wherein the receive filter (1) has series resonators (SR1, SR2), which operate with surface acoustic waves and are arranged in the sub-paths (RX1, RX2) of the receive path.

8. Duplexer according to claim 3, wherein the receive filter (1) has a series resonator (SR), which operates with SAW or BAW and is connected before the DMS track.

9. Duplexer according to claim 3, wherein the receive filter (1) has a parallel resonator (PR), which operates with SAW or BAW and is arranged in a transverse branch that is connected before the DMS track.

10. Duplexer according to claim 1, in which the transmit filter (2) has several resonators, which operate with bulk acoustic waves and are connected to each other in a ladder-type arrangement.

11. Duplexer according to claim 1, in which the transmit filter (2) has a resonator stack, which is arranged in the transmit path (TX) and has two resonators (R1, R2) stacked one above the other.

12. Duplexer according to claim 11, in which the resonators (R1, R2) have a common electrode.

13. Duplexer according to claim 11, in which an acoustic, semi-transparent coupling layer (K1) is arranged between the resonators (R1, R2).

14. Duplexer according to claim 13, with another resistant stack (6′), which is arranged in the transmit path (TX) and has resonators (R1′, R2′) and an acoustic, semi-transparent coupling layer (K2) arranged therebetween, wherein an electrode (E3) of the first resonator stack (6) facing the coupling layer (K1) is connected electrically to an electrode (E3′) of the other resonator stack facing the coupling layer (K2) of the other resonator stack (6′).

15. Duplexer according to claim 13, in which at least one transverse branch with a parallel resonator (R3, R4) arranged in this branch and operating with bulk acoustic waves is provided between the transmit path (TX) and ground.

16. Duplexer according to claim 13, in which a series resonator operating with bulk acoustic waves is provided in the transmit path (TX).

17. Duplexer according to claim 1, wherein the receive filter (1) is constructed in a SAW chip (CH1), wherein the transmit filter (2) is constructed in a BAW chip (CH2), wherein the SAW chip and the BAW chip are mounted on a common carrier substrate (3) and connected electrically to this substrate.

18. Duplexer according to claim 17, wherein the SAW chip and the BAW chip are spaced apart from each other by at least λ/1000, wherein λ is the wavelength of the electrical wave at a center frequency of the component.

19. Duplexer according to claim 17, in which the SAW chip and the BAW chip are mounted on the carrier substrate (3) in a flip-chip arrangement.

20. Duplexer according to claim 17, in which the SAW chip and the BAW chip are mounted on the carrier substrate (3) by means of wire bonding.

21. Duplexer according to claim 1, in which the transmit filter (2) is connected asymmetrically on the input side and on the output side.

22. Duplexer according to claim 1, in which the transmit filter (2) executes an impedance transform.

23. Duplexer according to claim 1, in which the receiver filter (1) executes an impedance transform.

24. Duplexer according to claim 1, in which the receive filter (1) has an asymmetric input.
